(19) United States
(12) Patent Application Publication
(10) Pub. No.: US 2004/0017188 A1
(43) Pub. Date: Jan. 29, 2004

(54) Magnetic detection apparatus

(75) Inventors: Masahiro Yokotani, Tokyo (JP); Izuru Shinjo, Tokyo (JP); Naohiro Mishiro, Tokyo (JP); Naoki Hiraoka, Tokyo (JP)

Correspondence Address: SUGHRUE MION, PLLC, 2100 PENNSYLVANIA AVENUE, N.W., WASHINGTON, DC, 20037, US

(73) Assignee: MITSUBISHI DENKI KABUSHIKI KAISHA

(21) Appl. No.: 10/308,111

(22) Filed: Dec. 3, 2002

(30) Foreign Application Priority Data
Jul. 23, 2002 (JP) 2002-213837

(51) Int. Cl. G01B 7/30; G01R 33/09

(52) U.S. Cl. 324/207.21; 324/207.25

(57) ABSTRACT

A magnetic detection apparatus can accurately detect the rotational position of a magnetic moving member even when intervals between adjacent teeth formed thereon and the circumferential width of each tooth itself are both small and when an opposing distance between the magnetic moving member and first and second magnetoresistive segments is large. A processing circuit is arranged apart from the magnetic moving member on a plane thereof, which is formed on its periphery with the teeth. The processing circuit has a bridge circuit including the first magnetoresistive segment and the second magnetoresistive segment. A magnet applies a magnetic field to the first and second magnetoresistive segments, and to the magnetic moving member in a direction of an axis of rotation thereof. The first magnetoresistive segment is arranged substantially on a center line passing through the center of the circumferential width of the magnet, when viewed along the axis of rotation of the magnetic moving member.

### BACKGROUND OF THE INVENTION

1. Field of the Invention

The present invention relates to a magnetic detection apparatus for detecting the rotational position of a magnetic moving member that is formed on its periphery with teeth and rotates in a circumferential direction, for example.

2. Description of the Related Art

FIG. 11(a) is a perspective view of a known magnetic detection apparatus. FIG. 11(b) is a partial plan view of the magnetic detection apparatus of FIG. 11(a). FIG. 12 is an electric circuit diagram of the known magnetic detection apparatus. FIG. 13 shows operational waveform diagrams of the known magnetic detection apparatus.

The magnetic detection apparatus includes: a processing circuit 20 arranged apart from a magnetic moving member 1 on a plane thereof, which is formed on its periphery with teeth 1a and rotates around an axis of rotation or rotation shaft 4 in a circumferential direction, the processing circuit 20 having a bridge circuit comprising a magnetoelectric conversion element in the form of a magnetoresistive segment 2a, and fixed resistors 12b, 12c and 12d; and a magnet 3 that applies a magnetic field to the magnetoresistive segment 2a and also applies a magnetic field to the magnetic moving member 1 in the direction of the axis of rotation thereof. In addition, the processing circuit 20 incorporates therein an amplifier circuit 13, which amplifies a signal whose voltage is varied depending on a change in the resistance of the magnetoresistive segment 2a, a comparison circuit 14 and an output circuit 15.

With the magnetic detection apparatus as constructed above, the magnetic moving member 1 is caused to rotate in synchronization with the rotation of the rotation shaft 4, so that the magnetic field applied to the magnetoresistive segment 2a from the magnet 3 is accordingly varied. As a result, the resistance value of the magnetoresistive segment 2a changes between the time when a tooth 1a of the magnetic moving member 1 comes to face the magnetoresistive segment 2a and the time when a groove 1b of the magnetic moving member 1 comes to face the magnetoresistive segment 2a, as illustrated in FIG. 13. Thus, the output of the amplifier circuit 13 also changes accordingly. Then, the output of the amplifier circuit 13 is waveform shaped by means of the comparison circuit 14, so that the output terminal 16 of the processing circuit 20 finally generates a final output signal of “1” or “0” corresponding to a tooth 1a or a groove 1b of the magnetic moving member 1.

However, the known magnetic detection apparatus as described above has the following problem. That is, when intervals between adjacent teeth 1a and the circumferential width of each tooth 1a are both small, and when an opposing space (hereinafter called a “GAP”) between the circumferential surface of the magnetic moving member 1 and the magnetoresistive segment 2a is large, as shown in FIG. 14, there might often arise such a case where a final output signal of “1” or “0” is not obtained from the output terminal 16 of the processing circuit 20, as shown in FIG. 15.

### SUMMARY OF THE INVENTION

The present invention is intended to obviate the above-mentioned problem, and has for its object to provide a magnetic detection apparatus which is capable of accurately detecting the rotational position of a magnetic moving member even when the intervals between adjacent teeth formed thereon and the circumferential width of each tooth itself are both small or limited and when an opposing space or distance between the circumferential surface of the magnetic moving member and each magnetoresistive segment is large.

Bearing the above object in mind, the present invention resides in a magnetic detection apparatus which includes: a processing circuit having convex portions formed on its periphery and being arranged apart from a magnetic moving member on a plane thereof, the processing circuit including a bridge circuit comprising at least a first magnetoelectric conversion element and a second magnetoelectric conversion element; and a magnet for applying a magnetic field to the first magnetoelectric conversion element and the second magnetoelectric conversion element and also applying a magnetic field to the magnetic moving member in a direction of an axis of rotation of the magnetic moving member. The first magnetoelectric conversion element is arranged on a center line passing through the center of a circumferential width of the magnet when viewed along the direction of the axis of rotation of the magnetic moving member.

According to the above arrangement, it is possible to achieve excellent detection performance even when the intervals between adjacent convex portions and the width in a direction of movement of each convex portion itself are small and when an opposing space or distance between the first and second magnetoelectric conversion elements and the magnetic moving member is large.

The above and other objects, features and advantages of the present invention will become more readily apparent to those skilled in the art from the following detailed description of preferred embodiments of the present invention taken in conjunction with the accompanying drawings.

### BRIEF DESCRIPTION OF THE DRAWINGS

FIG. 1(a) is a perspective view of a magnetic detection apparatus according to a first embodiment of the present invention.

FIG. 1(b) is a partial plan view of the magnetic detection apparatus of FIG. 1(a).

FIG. 1(c) is a view showing a pattern of magnetoresistive segments of FIG. 1(a).

FIG. 2 shows operational waveform diagrams of the magnetic detection apparatus of FIGS. 1(a) through FIG. 1(c).

FIG. 3(a) is a perspective view of a magnetic detection apparatus according to a second embodiment of the present invention.

FIG. 3(b) is a partial plan view of the magnetic detection apparatus of FIG. 3(a).

FIG. 3(c) is a view showing a pattern of magnetoresistive segments of FIG. 3(a).

FIG. 4 shows operational waveform diagrams of the magnetic detection apparatus of FIGS. 3(a) through 3(c).

FIG. 5 is a view showing the operational waveform of the magnetic detection apparatus of FIGS. 1(a) through 1(c) and the operational waveform of the magnetic detection apparatus of FIG. 3(a) through 3(c) overlapped one over the other.

FIG. 6(a) is a perspective view of a magnetic detection apparatus according to a third embodiment of the present invention.

FIG. 6(b) is a partial plan view of the magnetic detection apparatus of FIG. 6(a).

FIG. 6(c) is a view showing a pattern of magnetoresistive segments of FIG. 6(a).

FIG. 7 shows operational waveform diagrams of the magnetic detection apparatus of FIGS. 6(a) through 6(c).

FIG. 8 is a view showing the relation between a segment pitch N and a differential amplification output minimum amplitude in a magnetic detection apparatus according to a fourth embodiment of the present invention.

FIG. 9 is a view showing the relation between a pitch of projected members and a differential amplifier output minimum amplitude in a magnetic detection apparatus according to a fifth embodiment of the present invention.

FIG. 10 is a view showing an MR loop characteristic of a GMR element in the magnetic detection apparatus according to the fifth embodiment of the present invention.

FIG. 11(a) is a perspective view of a known magnetic detection apparatus.

FIG. 11(b) is a partial plan view of the magnetic detection apparatus of FIG. 11(a).

FIG. 12 is an electric circuit diagram of the known magnetic detection apparatus.

FIG. 13 shows operational waveform diagrams of the magnetic detection apparatus of FIGS. 11(a) and 11(b).

FIG. 14(a) is a perspective view of another known magnetic detection apparatus.

FIG. 14(b) is a partial plan view of the magnetic detection apparatus of FIG. 14(a).

FIG. 15 shows operational waveform diagrams of the magnetic detection apparatus of FIGS. 14(a) and 14(b).

### DESCRIPTION OF THE PREFERRED EMBODIMENTS

Now, preferred embodiments of the present invention will be described below in detail while referring to the accompanying drawings. The same or corresponding parts of the following preferred embodiments of the present invention as those in the known apparatuses described above will be identified by the same symbols.

Embodiment 1

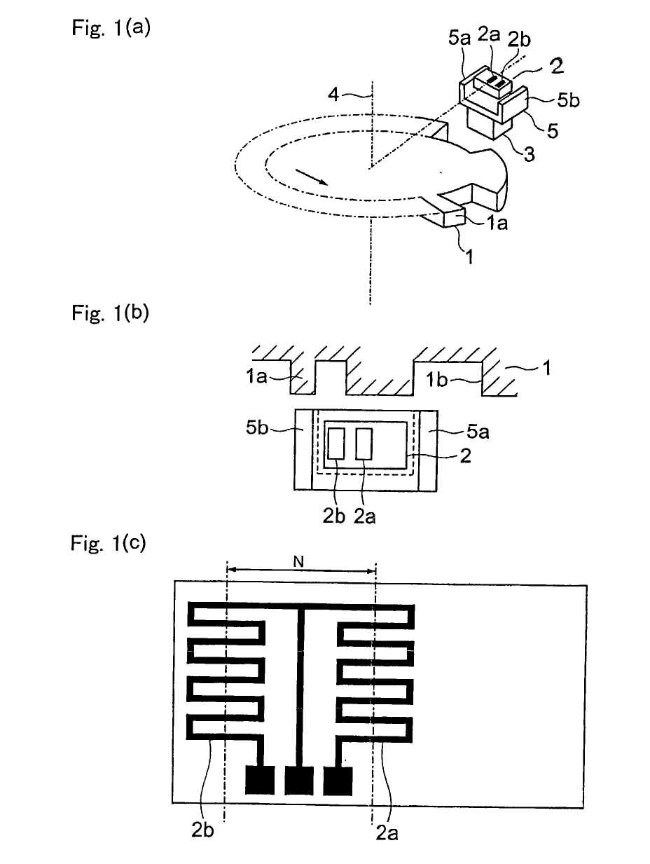

FIG. 1(a) is a perspective view of a magnetic detection apparatus according to a first embodiment of the present invention. FIG. 1(b) is a partial plan view of the magnetic detection apparatus of FIG. 1(a). FIG. 1(c) is a view showing a pattern of magnetoresistive segments of FIG. 1(a).

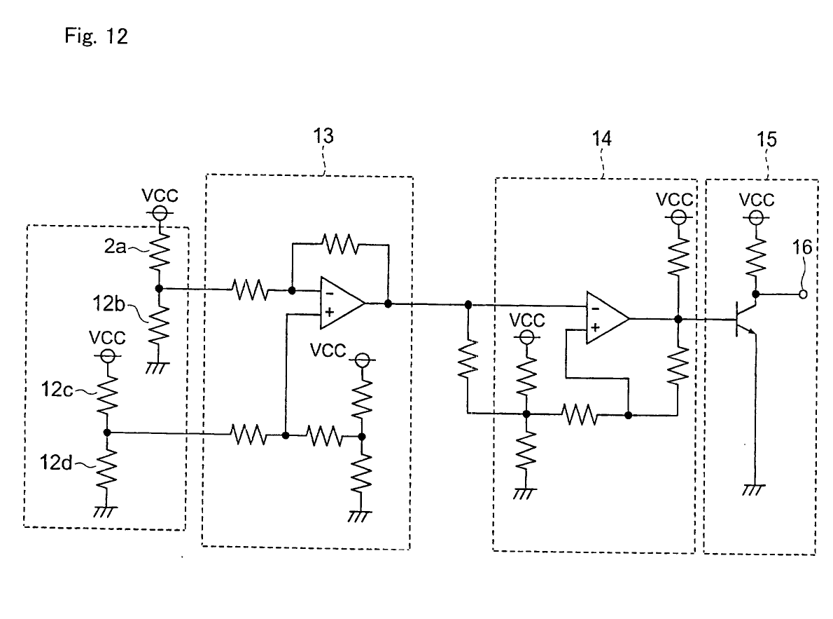

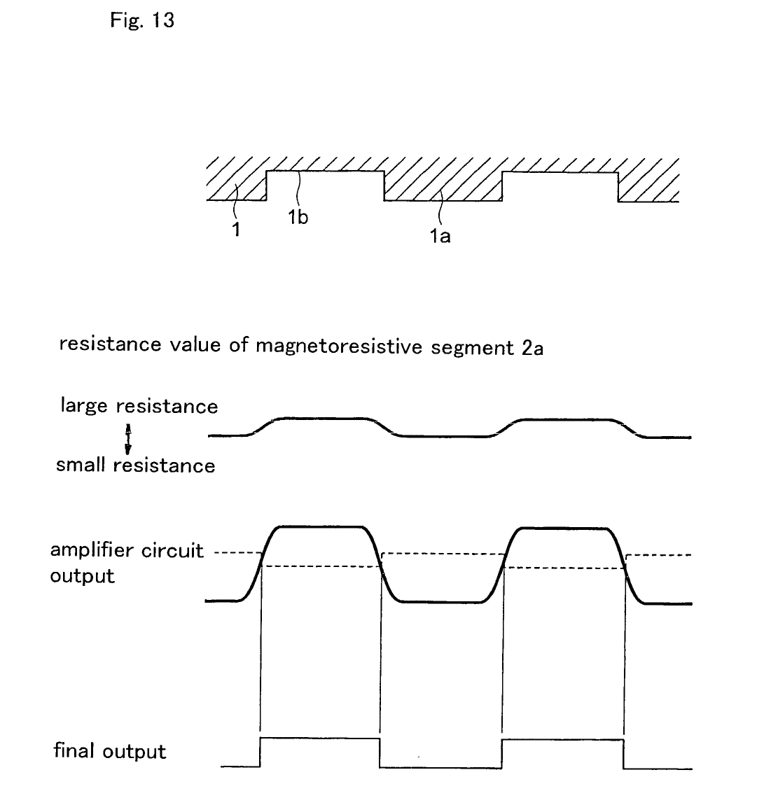

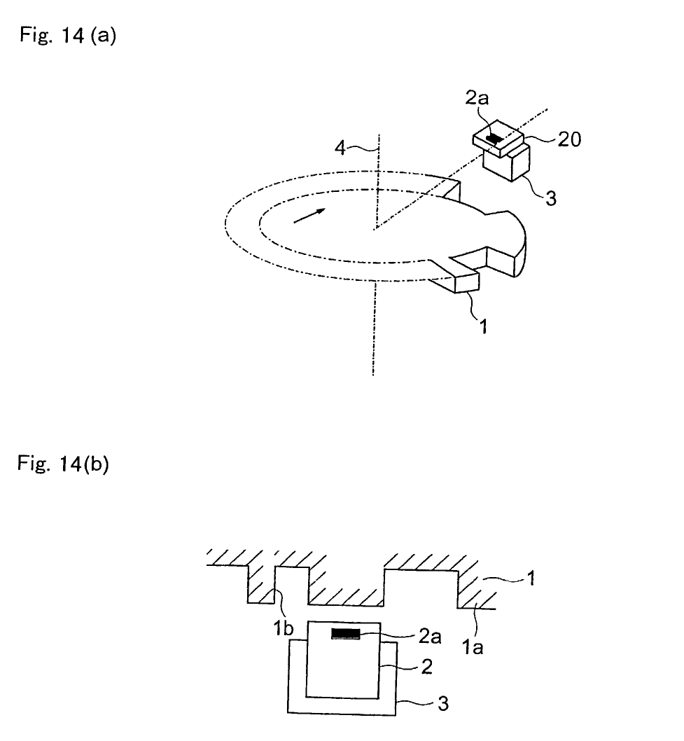

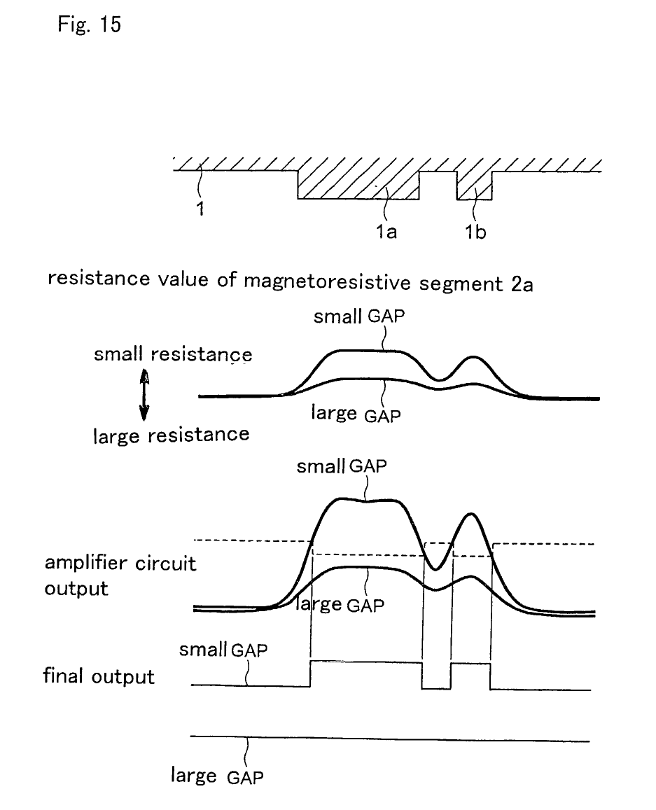

As shown in FIGS. 1(a) through 1(c), the magnetic detection apparatus according to the first embodiment includes a processing circuit 2 being arranged apart from a magnetic moving member 1 on a plane thereof, which is formed on its periphery with convex portions in the form of teeth 1a and rotates around an axis of rotation or rotation shaft 4 in a circumferential direction, and having a bridge circuit comprising a first magnetoresistive segment 2a and a second magnetoresistive segment 2b, which act as magnetoelectric conversion elements, and fixed resistors 12c and 12d (see FIG. 12), a magnet 3 for applying a magnetic field to the first and second magnetoresistive segments 2a, 2b as well as applying a magnetic field to the magnetic moving member 1 in a direction of the axis of rotation thereof, and a magnetic guide 5 of a magnetic material arranged between the processing circuit 2 and the magnet 3 for preventing dispersion of a magnetic flux from the magnet 3. The magnetic guide 5 has a pair of projected members 5a, 5b arranged in a circumferentially spaced and opposed relation with respect to each other. In addition, the processing circuit 2 incorporates therein an amplifier circuit 13, which amplifies a signal whose voltage is varied depending on a change in the resistances of the magnetoresistive segments 2a, 2b, respectively, a comparison circuit 14 and an output circuit 15 (see FIG. 12).

Note that the bridge circuit is different from the aforementioned known one shown in FIG. 12 in that the fixed resistor 12b of the latter is replaced by the second magnetoresistive segment 2b.

The first magnetoresistive segment 2a is arranged substantially on a widthwise central line passing through the center of the circumferential width of the magnet 3, and substantially on a center line between the pair of first and second projected members 5a, 5b, when viewed along the direction of the axis of rotation of the magnetic moving member 1. The second magnetoresistive segment 2b is arranged on the second projected member 5b side.

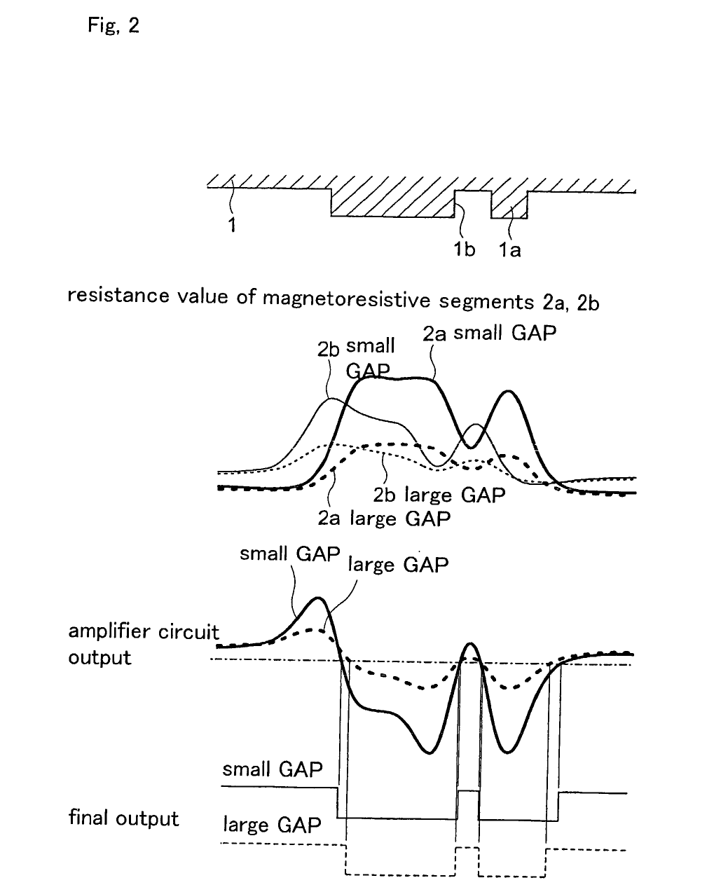

With the magnetic detection apparatus as constructed above, the magnetic moving member 1 is caused to rotate in synchronization with the rotation of the rotation shaft 4, so that the magnetic fields applied to the first and second magnetoresistive segments 2a, 2b from the magnet 3 are accordingly varied. As a result, the resistance value of each of the first and second magnetoresistive segments 2a, 2b changes between the time when a tooth 1a of the magnetic moving member 1 comes to face the first or second magnetoresistive segment 2a or 2b and the time when a groove 1b of the magnetic moving member 1 comes to face the first or second magnetoresistive segment 2a or 2b, as illustrated in FIG. 2. Thus, the output of the amplifier circuit 13 also changes accordingly. Then, the output of the amplifier circuit 13 is waveform shaped by means of the comparison circuit 14 so that the output terminal 16 of the processing circuit 2 finally generates a final output signal of “1” or “0” corresponding to a tooth 1a or a groove 1b of the magnetic moving member 1.

In this embodiment, as can be seen from FIG. 2, the intervals between adjacent or successive teeth 1a and the circumferential width of each tooth 1a are both small or limited, so that a final output signal of “1” or “0” can be obtained from the output terminal 16 of the processing circuit 2 even when opposing spaces or distances GAP between the circumferential surface of the magnetic moving member 1 and each of the magnetoresistive segments 2a, 2b is large. As a consequence, the position detection accuracy of the magnetic detection apparatus for detecting the rotational position of the magnetic moving member 1 can be improved to a considerable extent.

Embodiment 2

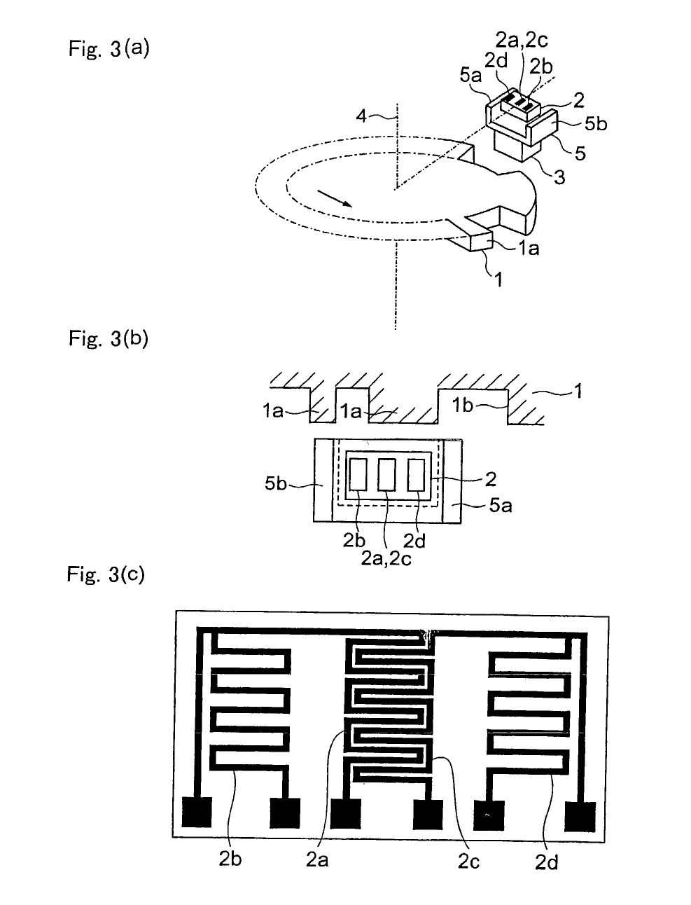

FIG. 3(a) is a perspective view showing a magnetic detection apparatus according to a second embodiment of the present invention. FIG. 3(b) is a partial plan view of the magnetic detection apparatus of FIG. 3(a). FIG. 3(c) is a view showing a pattern of magnetoresistive segments of FIG. 3(a).

In this second embodiment, the bridge circuit comprises a first magnetoresistive segment 2a, a second magnetoresistive segment 2b, a third magnetoresistive segment 2c and a fourth magnetoresistive segment 2d.

Here, note that the bridge circuit of this embodiment is different from the aforementioned known one shown in FIG. 12 in the following arrangement. That is, the fixed resistors 12b, 12c are replaced by the second and fourth magnetoresistive segments 2b, 2d, respectively, and the fixed resistor 12d is replaced by the third magnetoresistive segments 2c.

The first magnetoresistive segment 2a and the third magnetoresistive segments 2c are arranged substantially on a widthwise central line passing through the center of the circumferential width of the magnet 3, and substantially on a center line between the pair of first and second projected members 5a, 5b, when viewed along the direction of the axis of rotation of the magnetic moving member 1. The second magnetoresistive segment 2b is arranged on the second projected member 5b side, and the fourth magnetoresistive segment 2d is arranged on the first projected member 5a side.

In addition, a differential output is obtained from a first output at a first midpoint between the first magnetoresistive segment 2a and the second magnetoresistive segment 2b, and from a second output at a second midpoint between the third magnetoresistive segment 2c and the fourth magnetoresistive segment 2d.

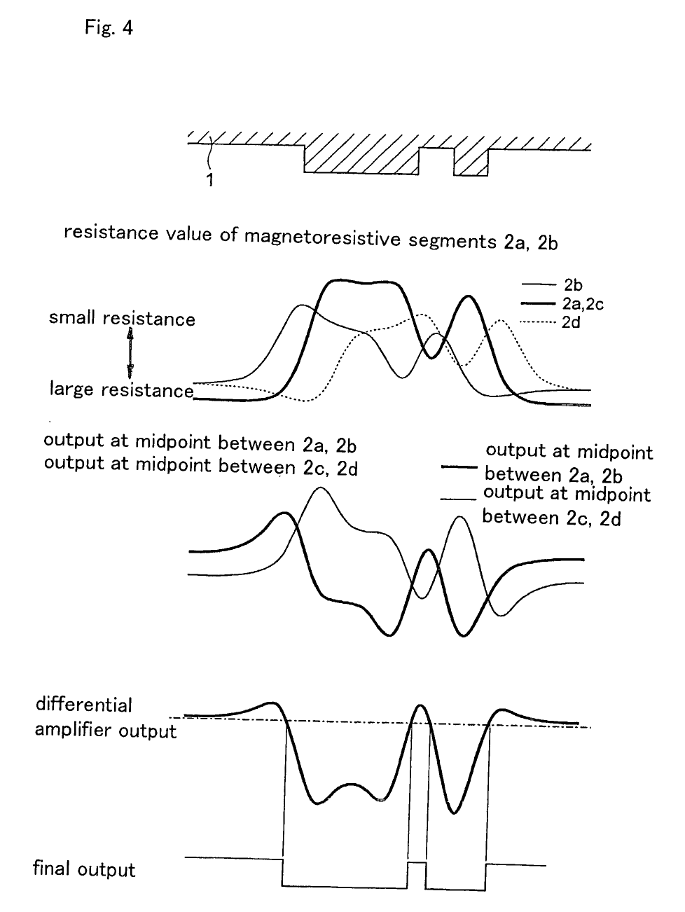

FIG. 4 shows operational waveform diagrams of the magnetic detection apparatus according to the second embodiment. The resistances of the first through fourth magnetoresistive segments 2a, 2b, 2c and 2d are changed in accordance with the shape (i.e., tooth 1a or groove 1b) of the magnetic moving member 1 so that there is obtained a differential amplification output between the first midpoint output at the first midpoint between the first magnetoresistive segment 2a and the second magnetoresistive segment 2b, and the second output at the second midpoint between the third magnetoresistive segment 2c and the fourth magnetoresistive segment 2d. This differential amplification output is waveform shaped to provide a final output signal of “1” or “0” corresponding to the shape (i.e., tooth 1a or groove 1b) of the magnetic moving member 1.

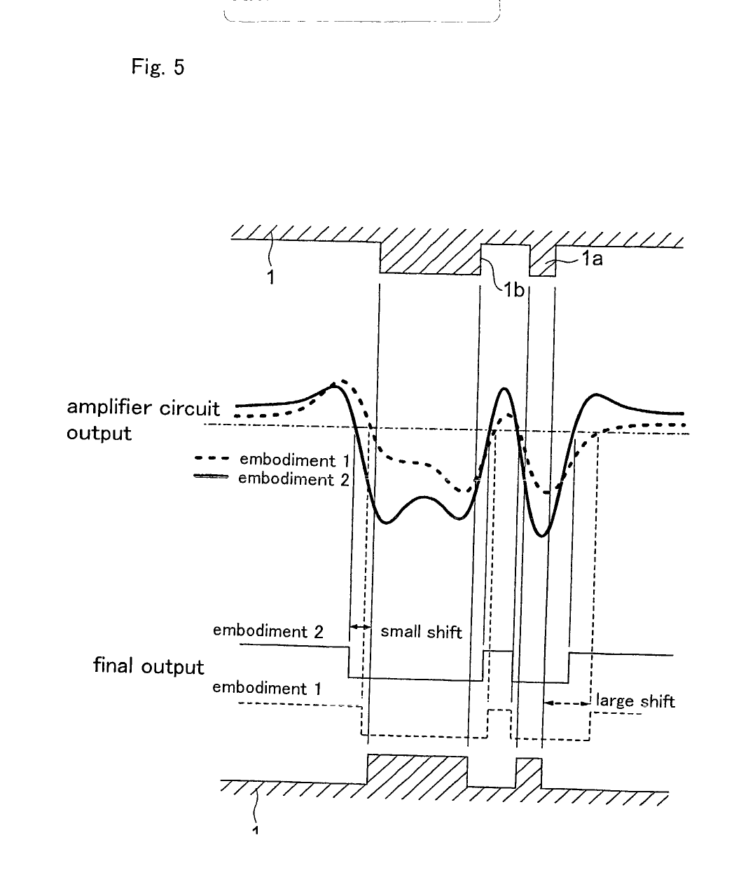

FIG. 5 is a view showing a comparison between the operational waveforms of the magnetic detection apparatuses according to the first and second embodiments. From this figure, it is found that when a comparison is made between points of maximum shifts or deviations of the detection positions in the first and second embodiments, the magnitudes of the maximum shifts or deviations of the detection positions are smaller in the second embodiment than in the first embodiment.

Embodiment 3

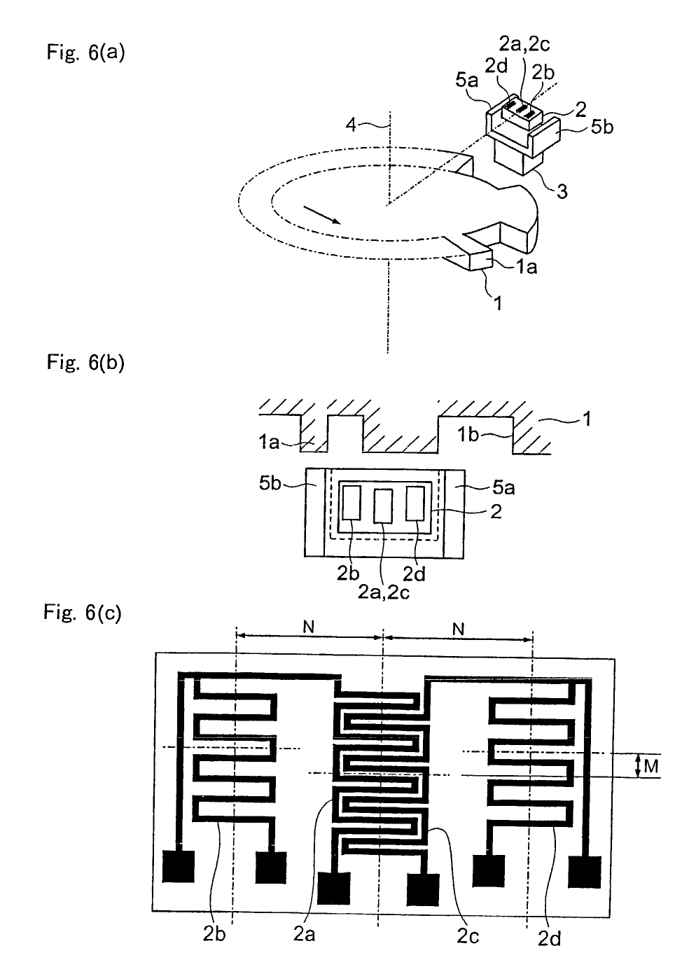

FIG. 6(a) is a perspective view showing a magnetic detection apparatus according to a third embodiment of the present invention. FIG. 6(b) is a partial plan view of the magnetic detection apparatus of FIG. 6(a). FIG. 6(c) is a view showing a pattern of magnetoresistive segments of FIG. 6(a).

In this third embodiment, the opposing distance of the peripheral surface of each tooth 1a to the first magnetoresistive segment 2a and the third magnetoresistive segment 2c is different from the opposing distance of the surface of each tooth 1a to the second magnetoresistive segment 2b and the fourth magnetoresistive segment 2d. The construction of this third embodiment other than the above is similar to that of the second embodiment.

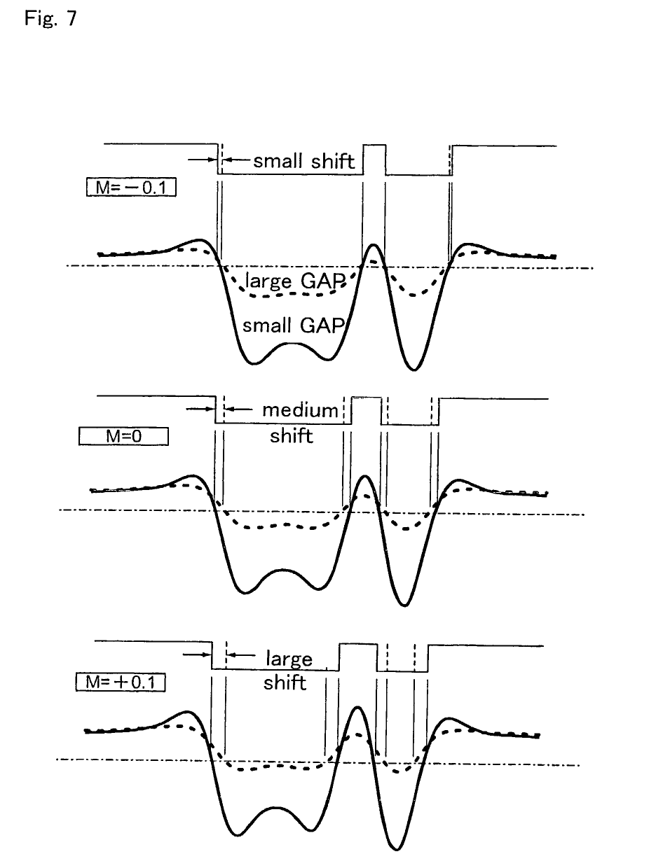

FIG. 7 shows operational waveform diagrams of the third embodiment when assuming that a difference between the opposing distances is M and the value of M is −0.1 mm, 0 mm and +0.1 mm, respectively, with the opposing distances GAP being large and small, respectively.

From this figure, it is found that the detection shifts or deviations both in large and small distances GAP are smaller when M=−0.1 mm than when M=+0.1 mm.

Thus, by adjusting the above-mentioned M in an appropriate manner, it is possible to suppress reduction in the detection performance of the apparatus which would be generated when the opposing distance GAP is large.

Embodiment 4

A fourth embodiment of the present invention shows an example in which accuracy in the detection of the rotational position of the magnetic moving member 1 can be improved by adjusting a distance or pitch N (see FIG. 6(c)) of the first magnetoresistive segment 2a and the third magnetoresistive segment 2c, which are arranged on the center line between the pair of projected members 5a, 5b, to the second magnetoresistive segment 2b and the fourth magnetoresistive segment 2d, which are arranged in the neighborhood of the projected members 5a, 5b, respectively.

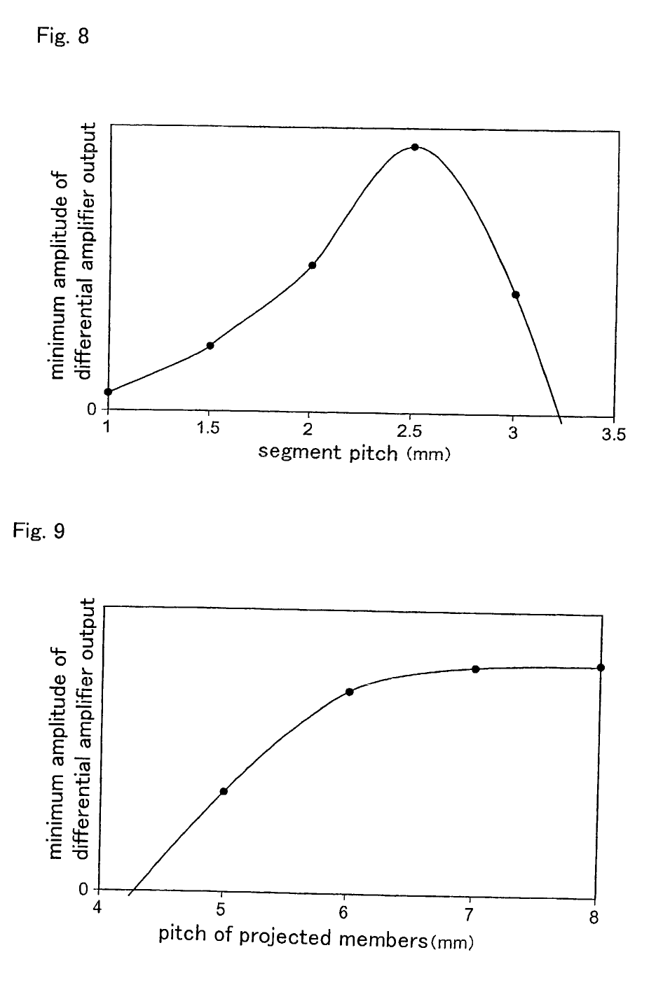

FIG. 8 is a view showing the relation between the segment pitch N and the minimum amplitude of the differential amplification output in the magnetic detection apparatus according to the fourth embodiment of the present invention. Here, the differential amplification output minimum amplitude means the amplitude of the output voltage of the differential amplifier 13 when a difference between the output voltage of the differential amplifier 13 and a comparison voltage is minimum. The lesser the value of the differential amplification output minimum amplitude, the worse becomes the position detection accuracy. In the example of FIG. 8, when the segment pitch N (i.e., interval between adjacent magnetoresistive segments) is within a range of 1.5 mm-3 mm, a differential amplification output capable of detecting the rotational position of the magnetic moving member 1 can be obtained, thereby ensuring high detection performance.

Embodiment 5

A fifth embodiment of the present invention shows an example in which accuracy in the detection of the rotational position of the magnetic moving member 1 can be improved by adjusting the opposing distance or pitch between the opposed projected members 5a, 5b in relation to the segment pitch N.

FIG. 9 shows, as an example, the relation between the distance between the projected members 5a, 5b (i.e., the pitch between the projected members) and the minimum amplitude of the differential amplification output when the segment pitch N is 2.5 mm. In the example of FIG. 9, when the pitch of the projected members is 5 mm or more (i.e., twice or more the magnetoresistive segment pitch N), it is possible to obtain an output of the differential amplifier 13 capable of detecting the rotational position of the magnetic moving member 1.

Embodiment 6

A sixth embodiment of the present invention shows an example in which a giant magnetoresistive element (hereinafter simply referred to as a “GMR element”) is used as a magnetic detection element.

The GMR element is a layered or stacked product in the form of a so-called artificial lattice film, which is formed by alternately stacking a plurality of magnetic layers and a plurality of non-magnetic layers each of a thickness of a few angstroms to a few tens of angstroms. (Fe/Cr)n, (permalloy/Cu/Co/Cu)n, and (Co/Cu)n (“n” is the number of stacked layers) are known as GMR elements. The GMR element has an MR effect (MR change rate) far greater than that of a conventional magnetoresistive element (hereinafter referred to as an “MR element”). The MR effect (i.e., the magnetic resistance or reluctance) of the GMR element depends solely on a relative angle included by the directions of magnetization of the adjacent magnetic layers, so that the GMR element has the same change in resistance with respect to the current flowing through the GMR element irrespective of the direction of an external magnetic field applied thereto relative to the direction of flow of the current. However, the GMR element can have magnetic anisotropy by narrowing the width of a magnetoresistive pattern.

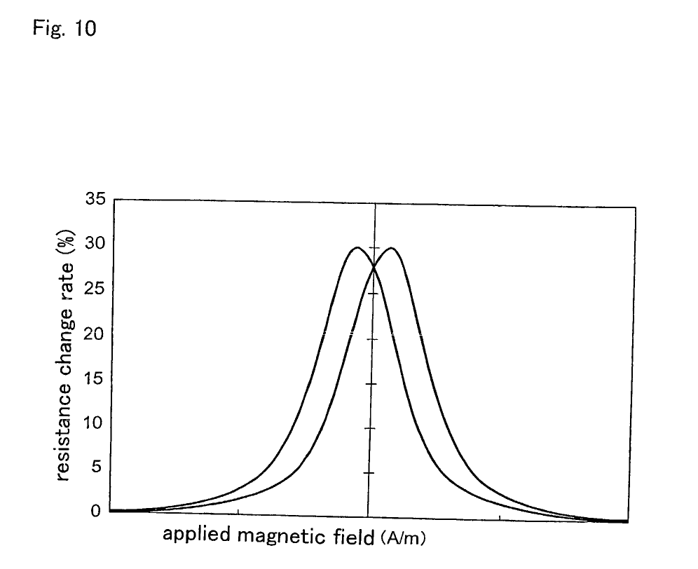

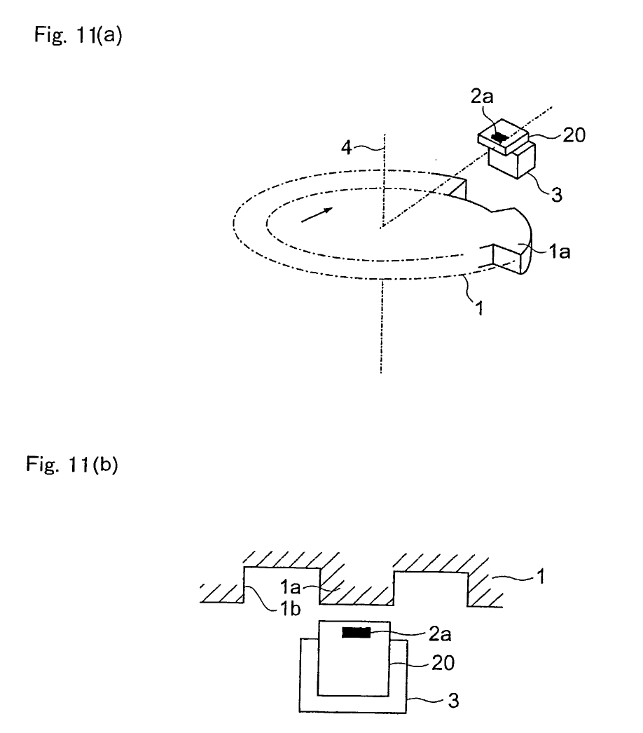

Moreover, the GMR element has hysteresis in the change of resistance caused by a change in the magnetic field applied thereto, and it also has a temperature characteristic, especially a large temperature coefficient. An MR loop characteristic of the GMR element is illustrated in FIG. 10.

In this manner, by using the GMR element as a magnetoelectric conversion element, the signal-to-noise ratio (S/N ratio) can be improved, and noise immunity can be increased.

In addition, although in the above-mentioned embodiments, the magnetic moving member 1 is of a disk shape formed on its periphery with the teeth 1a and rotates in its circumferential direction, it is of course not limited to such a shape and operation but may comprise a magnetic moving member capable of performing linear reciprocating motion for example.

In this case, a magnetic field is applied from the magnet to the magnetic moving member in a vertical direction perpendicular to a plane formed by the linear movement of the magnetic moving member, and the first magnetoelectric conversion element is arranged substantially on a center line of the magnet on a line on which it opposes to the magnetic moving member when viewed along the vertical direction.

As described in the foregoing, the present invention provides the following excellent advantages.

According to the present invention, there is provided a magnetic detection apparatus comprising: a processing circuit having convex portions formed on its periphery and being arranged apart from a magnetic moving member on a plane thereof, the processing circuit including a bridge circuit comprising at least a first magnetoelectric conversion element and a second magnetoelectric conversion element; and a magnet for applying a magnetic field to the first magnetoelectric conversion element and the second magnetoelectric conversion element and also applying a magnetic field to the magnetic moving member in a direction of an axis of rotation of the magnetic moving member. The first magnetoelectric conversion element is arranged on a center line passing through the center of a circumferential width of the magnet when viewed along the direction of the axis of rotation of the magnetic moving member. With the above arrangement, it is possible to achieve excellent detection performance even when the intervals between adjacent convex portions and the width in a direction of movement of each convex portion itself are small and when an opposing space or distance GAP between the first and second magnetoelectric conversion elements and the magnetic moving member is large.

Preferably the magnetic moving member comprises a disk-shaped member having teeth formed on its periphery and being movable in a circumferential direction thereof. Thus, excellent detection performance can be obtained even when the intervals between adjacent teeth and the circumferential width of each tooth itself are small and when an opposing space or distance GAP between the first and second magnetoelectric conversion elements and the magnetic moving member is large.

Preferably, the magnetic detection apparatus further comprises a magnetic guide arranged between the processing circuit and the magnet and having a pair of projected members in an opposed and spaced relation with respect to each other in the circumferential direction of the magnetic moving member. The first magnetoelectric conversion element is arranged substantially on a center line between the pair of projected members, and the second magnetoelectric conversion element is arranged on a side of one of the pair of projected members. Thus, it is possible to achieve excellent detection performance even when the intervals between adjacent teeth and the circumferential width of each tooth itself are small and when an opposing space or distance GAP between the first and second magnetoelectric conversion elements and the magnetic moving member is large.

Preferably, the bridge circuit comprises the first magnetoelectric conversion element, the second magnetoelectric conversion element, a third magnetoelectric conversion element arranged substantially on a center line between the pair of projected members, and a fourth magnetoelectric conversion element arranged on a side of the other one of the pair of projected members. A differential output is obtained from an output at a midpoint between the first magnetoelectric conversion element and the second magnetoelectric conversion element and from an output at a midpoint between the third magnetoelectric conversion element and the fourth magnetoelectric conversion element. Accordingly, the detection performance of the apparatus can be further improved.

Preferably, an opposing distance of a peripheral surface of each of the teeth to the first magnetoelectric conversion element and the third magnetoelectric conversion element is adjusted in relation to an opposing distance of the peripheral surface of each of the teeth to the second magnetoelectric conversion element and the fourth magnetoelectric conversion element. Thus, by adjusting the opposing distances, it is possible to suppress reduction in the detection performance of the apparatus which would be generated when the opposing space GAP is increased.

Preferably, a circumferential distance between the second magnetoelectric conversion element and the fourth magnetoelectric conversion element is adjusted in relation to a circumferential distance between the first magnetoelectric conversion element and the third magnetoelectric conversion element, whereby the detection performance of the apparatus can be improved.

Preferably, an opposing distance between the opposed projected members is adjusted in relation to a circumferential distance between the first magnetoelectric conversion element and the second magnetoelectric conversion element and a circumferential distance between the third magnetoelectric conversion element and the fourth magnetoelectric conversion element, whereby the detection performance of the apparatus can be further improved.

Preferably, each of the magnetoelectric conversion elements comprises a giant magnetoresistive element (GMR element), so the SN ratio can be improved and noise immunity can also be enhanced.

While the invention has been described in terms of preferred embodiments, those skilled in the art will recognize that the invention can be practiced with modifications within the spirit and scope of the appended claims.

What is claimed is:

1. A magnetic detection apparatus comprising:
a processing circuit having convex portions formed on its periphery and being arranged apart from a magnetic moving member on a plane thereof, said processing circuit including a bridge circuit comprising at least a first magnetoelectric conversion element and a second magnetoelectric conversion element; and
a magnet for applying a magnetic field to said first magnetoelectric conversion element and said second magnetoelectric conversion element and also applying a magnetic field to said magnetic moving member in a direction of an axis of rotation of said magnetic moving member;
wherein said first magnetoelectric conversion element is arranged on a center line passing through the center of a circumferential width of said magnet when viewed along the direction of said axis of rotation of said magnetic moving member.

2. The magnetic detection apparatus according to claim 1, wherein said magnetic moving member comprises a disk-shaped member having teeth formed on its periphery and being movable in a circumferential direction thereof.

3. The magnetic detection apparatus according to claim 2, further comprising a magnetic guide arranged between said processing circuit and said magnet and having a pair of projected members in an opposed and spaced relation with respect to each other in the circumferential direction of said magnetic moving member, wherein said first magnetoelectric conversion element is arranged substantially on a center line between said pair of projected members, and said second magnetoelectric conversion element is arranged on a side of one of said pair of projected members.

4. The magnetic detection apparatus according to claim 3, wherein said bridge circuit comprises said first magnetoelectric conversion element, said second magnetoelectric conversion element, a third magnetoelectric conversion element arranged substantially on a center line between said pair of projected members, and a fourth magnetoelectric conversion element arranged on a side of the other one of said pair of projected members, and a differential output is obtained from an output at a midpoint between said first magnetoelectric conversion element and said second magnetoelectric conversion element and from an output at a midpoint between said third magnetoelectric conversion element and said fourth magnetoelectric conversion element.

5. The magnetic detection apparatus according to claim 4, wherein an opposing distance of a peripheral surface of each of said teeth to said first magnetoelectric conversion element and said third magnetoelectric conversion element is adjusted in relation to an opposing distance of the peripheral surface of each of said teeth to said second magnetoelectric conversion element and said fourth magnetoelectric conversion element.

6. The magnetic detection apparatus according to claim 4, wherein a circumferential distance between said second magnetoelectric conversion element and said fourth magnetoelectric conversion element is adjusted in relation to a circumferential distance between said first magnetoelectric conversion element and said third magnetoelectric conversion element.

7. The magnetic detection apparatus according to claim 4, wherein an opposing distance between said opposed projected members is adjusted in relation to a circumferential distance between said first magnetoelectric conversion element and said second magnetoelectric conversion element and a circumferential distance between said third magnetoelectric conversion element and said fourth magnetoelectric conversion element.

8. The magnetic detection apparatus according to claim 1, wherein each of said first and second magnetoelectric conversion elements comprises a giant magnetoresistive element (GMR element).
